(19) United States
(12) Patent Application Publication
(10) Pub. No.: US 2016/0006444 A1
(43) Pub. Date: Jan. 7, 2016

(54) DIGITALLY CONTROLLED DELAY-LOCKED LOOP REFERENCE GENERATOR

(71) Applicant: Silicon Storage Technology, Inc., San Jose, CA (US)

(72) Inventors: Yao Zhou, Shanghai (CN); Yuou Cao, Shanghai (CN); Xiaozhou Qian, Shanghai (CN); Ning Bai, Shanghai (CN); Xinyan Xu, Shanghai (CN)

(21) Appl. No.: 14/486,694

(22) Filed: Sep. 15, 2014

(30) Foreign Application Priority Data
Jul. 4, 2014 (CN) 201410401923.8

(51) Int. Cl. H03L 7/14; H03L 7/083; H03L 7/081

(52) U.S. Cl. CPC H03L 7/14; H03L 7/0814; H03L 7/083

(57) ABSTRACT

A system and method for a digitally controlled delay-locked loop reference generator is disclosed.

### TECHNICAL FIELD

A system and method for a digitally controlled delay-locked loop reference generator is disclosed.

### BACKGROUND OF THE INVENTION

Electronic devices increasingly demand extremely high speed memory devices. For example, systems are being contemplated that would require read operations from flash memory devices to occur at a speed of over 160 MHz. Such systems will require extremely precise timing controllers. Prior art systems typically utilize delay-locked loop (DLL) devices. DLL systems require a constant input reference clock to lock the delay timing. If there is a glitch in the input reference clock (as might be caused by noise, electromagnetic interference, etc.), then a DLL system can create a false lock when the input reference clock is absent for even a clock cycle or two.

What is needed is an improved timing controller for generating a reference signal that can continue to operate when an input reference clock is temporarily absent.

### SUMMARY OF THE INVENTION

A system and method for a digitally controlled delay-locked loop reference generator is disclosed. The system can continue operating even when the input reference clock is temporarily absent.

### BRIEF DESCRIPTION OF THE DRAWINGS

FIG. 1 depicts an embodiment of a reference signal generator.

FIG, 2 depicts an embodiment of a current control delay loop.

FIG. 3 depicts another embodiment of a reference signal generator.

### DETAILED DESCRIPTION OF THE PREFERRED EMBODIMENTS

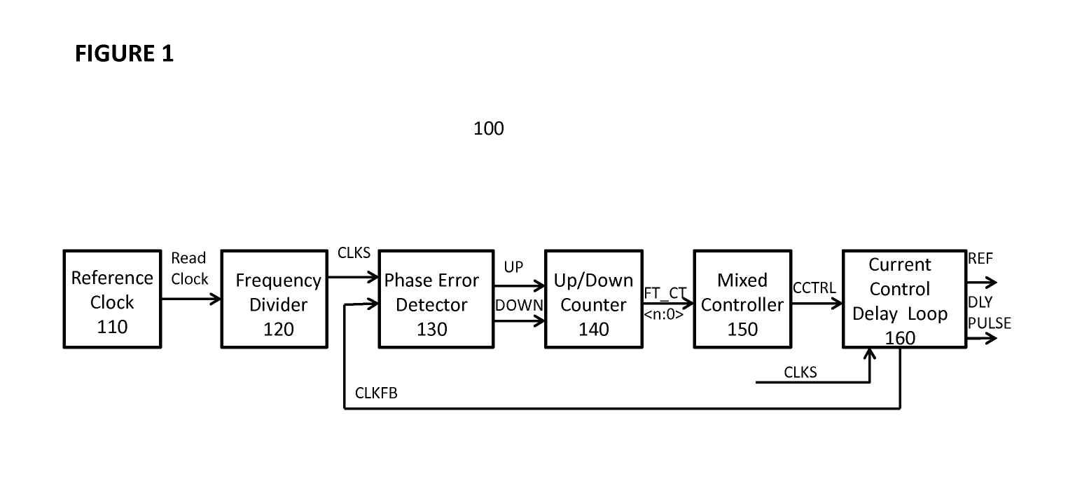

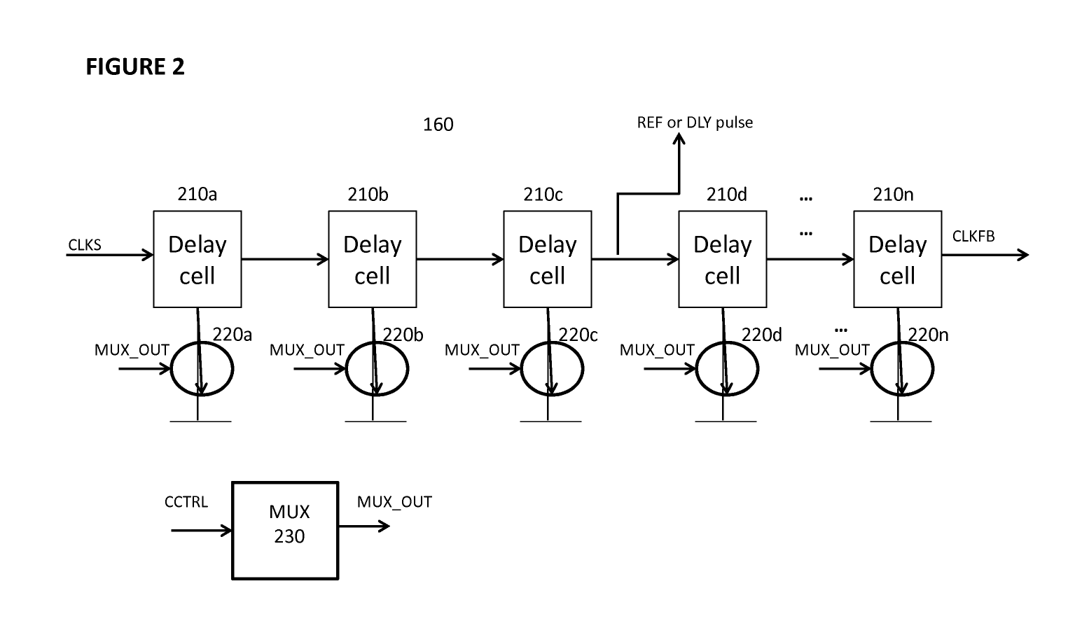

An embodiment of reference signal generation system 100 is depicted in FIG. 1. Reference signal generation system 100 comprises reference clock 110, frequency divider 120, phase error detector 130, up/down counter 140, mixed controller 150, and current control delay loop 160, coupled together as shown.

Reference clock 110 generates the signal labeled Read Clock, which is a clock signal of a constant frequency. Reference clock 110 can comprise, for example, a crystal oscillator as is known in the prior art. An example of a period for Read Clock is 10 ns.

Frequency divider 120 receives Read Clock and optionally generates the signal labeled CLKS, which is a clock signal of a constant frequency that is a fixed fraction of the frequency of Read Clock. For example, if the period of Read Clock is 10 ns, frequency divider 120 can be configured to divide the frequency by X. If X is, for example, equal to 4, then the period of CLKS will be 40 ns.

Phase error detector 130 receives CLKS as well as the signal labeled CLKFB from current control delay loop 160. Phase error detector 130 compares the relative phase of CLKS against CLKFB. If the two signals are out of phase, phase error detector 130 asserts either the UP output or the DOWN output. For example, if CLKS is out of phase with CLKFB in a negative amount, phase error detector 130 can assert the UP signal. If CLKS is out of phase with CLKFB in a positive amount, phase error detector 130 can assert the DOWN signal. If the two signals are in phase, neither UP nor DOWN are asserted.

Up/down counter 140 receives the UP signal and DOWN signal Up/down counter generates a digital signal labeled FT_CT <n:0>, which comprises n+1 bits. An example of a value for n is 3. The value of FT_CT is initial set to a mid-value position. For example, if n=3, the value of FT_CT might be set to 1000 initially. Thereafter, each time the UP signal is asserted, FT_CT will be increased by 1, and each time the DOWN signal is asserted, FT_CT will be decreased by 1.

Mixed controller 150 receives the FT_CT signal. In response to the value of FT_CT, mixed controller 150 will alter the value of its output, the signal labeled CCTRL, which is received by current control delay loop 160.

Current control delay loop 160 receives the signal CCTRL and alters a selection of internal gates in response to CCTRL. With reference to FIG. 2, in one embodiment current control delay loop 160 comprises a plurality of delay cells (which comprise one or more gates) gates in series with one another, here shown as delay cells 210a, 210b, 210c, 210d, . . . 210n (where n is an integer), with each delay cell 210a . . . 210n being controlled by a corresponding current source 220a, 220b, 220c, 220d, . . . 200n (where n is an integer), respectively. Each current source 220a, . . . 220n is controlled by the output MUX_OUT of multiplexor 230. MUX_Out selects the number of gates to use. If CCTRL is asserted, current control delay loop 160 will enable another gate to be used through multiplexor 220. This will increase (or decrease if a gate is disabled) the delay of CLKFB, which is the signal that emerges from the final gate. When the phase of CLKFB matches the phase of CLKS, the delay (charge current) will be locked (fixed) and no further alterations will be required.

Meanwhile, current control delay loop 160 can generate signals REF and DLY PULSE. REF is a desired delayed version of signal CLKS. For instance, it may be desirable to generate a signal that is a delayed version of CLKS by a certain amount of time (e.g., 10 ns delay). The signal DLY PULSE is asserted when the desired delay has been achieved (e.g., it can be activated after 10 ns has transpired after the beginning of a cycle of CLKS). The amount of the delay can be determined by deciding which output of which delay cell 210a . . . 210n to use.

Unlike in the prior art, if the Read Clock is corrupted by noise or other events, the system can continue to operate. Specifically, up/down counter 140 will continue outputting the value of FT_CT that was being output at the time when Read Clock was still intact. The delay loop of current control delay loop 160 will continue to operate.

It will be appreciated by one of ordinary skill in the art that frequency divider 120 is optional. Or if present, frequency divider 120 can be configured to perform division by 1 such that CLKS is the Read Clock signal.

In an alternative embodiment, instead of the design of FIG. 2, current control delay loop 160 can be configured to use CCTRL as an analog control signal to control a delay chain using the current value of CCTRL.

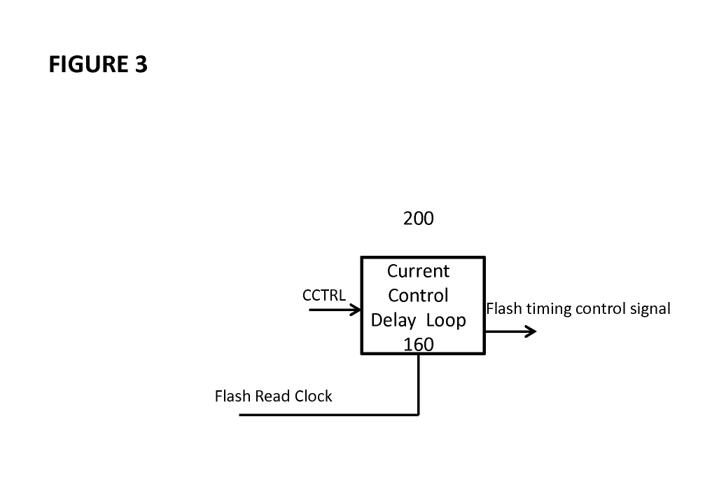

An alternative embodiment is shown in FIG. 3. FIG. 3 depicts reference signal generation system 200, which is similar to reference signal generation system 100, but current control delay loop 160 also receives a flash read clock. The flash read clock is the combination of a clock signal and a flash read enable signal. The signal CCTRL is used to control a slave delay chain within current control delay loop 160, and the flash read clock results in the generation of a flash timing control signal, which in turn can be used to control the reading of data from a flash memory array.

References to the present invention herein are not intended to limit the scope of any claim or claim term, but instead merely make reference to one or more features that may be covered by one or more of the claims. Materials, processes and numerical examples described above are exemplary only, and should not be deemed to limit the claims. It should be noted that, as used herein, the terms “over” and “on” both inclusively include “directly on” (no intermediate materials, elements or space disposed there between) and “indirectly on” (intermediate materials, elements or space disposed there between). Likewise, the term “adjacent” includes “directly adjacent” (no intermediate materials, elements or space disposed there between) and “indirectly adjacent” (intermediate materials, elements or space disposed there between). For example, forming an element “over a substrate” can include forming the element directly on the substrate with no intermediate materials/elements there between, as well as forming the element indirectly on the substrate with one or more intermediate materials/elements there between.

1. A system for generating a timing delay signal, comprising:
a phase error detector for determining the phase error between a first periodic signal and a second periodic signal;
a counter for receiving one or more outputs from the phase error detector and generating a digital signal;
a controller for receiving the digital signal and generating a signal to drive a current control delay loop, the current control delay loop generating the second periodic signal and the timing delay signal.

2. The system of claim 1, further comprising:
a reference clock for generating the first periodic signal;

3. The system of claim 1, further comprising:
a frequency divider for generating the first periodic signal in response to a third periodic signal.

4. The system of claim 3, further comprising:
a reference clock for generating the third periodic signal.

5. The system of claim 4, wherein the reference clock comprises a crystal oscillator.

6. The system of claim 3, wherein the frequency of the third periodic signal is an integer multiple of the frequency of the first periodic signal.

7. The system of claim 1, wherein the digital signal comprises at least four bits.

8. The system of claim 7, wherein the digital signal comprises at least eight bits.

9. The system of claim 1, wherein the counter increments the digital signal when one output is asserted and decrements the digital signal when another output is asserted.

10. The system of claim 2, wherein the counter increments the digital signal when one output is asserted and decrements the digital signal when another output is asserted.

11. The system of claim 3, wherein the counter increments the digital signal when one output is asserted and decrements the digital signal when another output is asserted.

12. The system of claim 4, wherein the counter increments the digital signal when one output is asserted and decrements the digital signal when another output is asserted.

13. The system of claim 5, wherein the counter increments the digital signal when one output is asserted and decrements the digital signal when another output is asserted.

14. The system of claim 1, wherein the timing delay signal is asserted after a time interval has elapsed after the beginning of a cycle of the first periodic signal, wherein the time interval is a predetermined portion of the period of the first periodic signal.

15. The system of claim 2, wherein the timing delay signal is asserted after a time interval has elapsed after the beginning of a cycle of the first periodic signal, wherein the time interval is a predetermined portion of the period of the first periodic signal.

16. The system of claim 3, wherein the timing delay signal is asserted after a time interval has elapsed after the beginning of a cycle of the first periodic signal, wherein the time interval is a predetermined portion of the period of the first periodic signal.

17. The system of claim 4, wherein the timing delay signal is asserted after a time interval has elapsed after the beginning of a cycle of the first periodic signal, wherein the time interval is a predetermined portion of the period of the first periodic signal.

18. A system for generating a timing delay signal, comprising:
a reference clock for generating a first periodic signal;
a frequency divider for generating a second periodic signal with a frequency that is a predetermined fraction of the frequency of the first periodic signal;
phase error detector for determining the phase error between the second periodic signal and a third periodic signal;
a counter for receiving one or more outputs from the phase error detector and generating a digital signal; and
a controller for receiving the digital signal and generating a signal to drive a current control delay loop, the current control delay loop generating the third periodic signal and the timing delay signal.

19. The system of claim 18, wherein the timing delay signal is asserted after a time interval has elapsed after the beginning of a cycle of the first periodic signal, wherein the time interval is a predetermined portion of the period of the first periodic signal.

20. The system of claim 18, wherein the timing delay signal is asserted after a time interval has elapsed after the beginning of a cycle of the second periodic signal, wherein the time interval is a predetermined portion of the period of the second periodic signal.
